(19) United States
(12) Patent Application Publication
(10) Pub. No.: US 2006/0065476 A1
(43) Pub. Date: Mar. 30, 2006

(54) Speaker system

(76) Inventor: David John Tasker, GOLD COAST (AU)

Correspondence Address: David John Tasker, P O Box 491, Gold Coast, 4220, AU

(21) Appl. No.: 10/535,071

(22) PCT Filed: Nov. 21, 2003
(86) PCT No.: PCT/AU03/01561

§ 371 Date: May 17, 2005

(30) Foreign Application Priority Data
Nov. 22, 2002 (AU) 2002302105
Sep. 26, 2003 (AU) 2003905238

(51) Int. Cl. H05K 5/00

(52) U.S. Cl. 181/155

(57) ABSTRACT

A speaker system which transmits sound to a listening area by reflection, the speaker system including at least one speaker enclosure comprising an enclosure housing at least one speaker and a device for reflecting sound into the listening area.

### FIELD OF THE INVENTION

The present invention relates to speaker systems.

### BACKGROUND OF THE INVENTION

The majority of conventional speakers consist of a transducer or transducers located on the front panel of the speaker, such that it radiates sound directly to the ear of a listener. Alternatively, some speaker systems are arranged so that the transducers radiate sound both directly and reflected to the listener. However, these conventional speaker systems have a number of problems associated with the dispersion of the bass frequencies at a uniform sound pressure level. For example, at low sound pressure levels, approximately 70 to 80 decibels, the dynamic upper bass frequencies can not be clearly heard. Furthermore, conventional speaker systems have a limited aural acoustic “sweet spot” of approximately 1 m². Diffraction and echo from the walls, floor and ceiling of a room cause sound waves to arrive at the ear at different times and some frequency bands overwhelm other frequency bands.

### SUMMARY OF THE INVENTION

According to a first aspect of the present invention, there is provided a speaker system which transmits sound to a listening area by reflection, the speaker system including at least one speaker enclosure comprising an enclosure housing at least one speaker enclosure and a device for reflecting sound into the listening area.

Throughout the specification, the speaker is understood to refer to a speaker enclosure, comprising components for the production of sound including at least one transducer for the conversion of electrical energy to acoustic energy.

Preferably, the at least one transducer includes an electro dynamic moving coil bass transducer and a compression driver. Preferably, the moving coil bass transducer has a diameter of 38 cm.

Throughout the specification, the listening area is understood to refer to the space in which a listener receives sound from the speaker system.

Preferably, the reflective horn is connected to one side of the enclosure. Preferably, the reflective horn includes a rear reflecting panel facing the at least one speaker at an angle. This angle is referred to as the “toe-in” angle. Preferably, the toe-in angle is 20° to 60°. More preferably, approximately 40°. Alternatively, the rear reflecting panel directly faces the at least one speaker.

Preferably, the at least one speaker is tilted relative to the rear reflecting panel at an angle. This angle is referred to as the tilt angle. Preferably, the tilt angle is 0° to 60°. Preferably, the tilt angle is dependent on the location of the at least one speaker relative to the floor. Preferably, the at least one speaker is inclined so as to direct sound to a listener in the listening area. Preferably, when the at least one speaker is at a height of 1 m to 1.5 m above the floor, the tilt angle is 0°. Preferably, the tilt angle increases when the at least one speaker is above 1.5 m or below 1 m. Preferably, when the at least one speaker enclosure rests on the floor, the tilt angle is approximately 30°. Preferably, when the at least one speaker is located approximately 3 cm above floor level, the tilt angle is approximately 30°.

Preferably, the rear reflecting panel is substantially vertical. The rear reflecting panel may be formed by a wall. Preferably, the reflective horn also includes a baffle panel. Preferably, the baffle panel also forms one of the walls of the enclosure. Preferably, the at least one transducer of the at least one speaker is located on the baffle panel. Preferably, the rear reflective panel faces the baffle panel at the toe-in angle. Preferably, the baffle panel is inclined to the rear reflective panel at the tilt angle. Preferably, the reflective horn also includes a top reflecting panel. The preferably top reflecting panel, in use, acts to prevent the substantial loss of sound from the top of the at least one speaker enclosure. Preferably, the top reflecting panel is connected to the rear reflecting panel at 50° to 150°. More preferably, the top reflecting panel is substantially horizontal. The top reflecting panel may be formed by a ceiling.

Preferably, the reflective horn also includes a bottom reflecting panel. The preferably bottom reflecting panel, in use, acts to prevent the substantial loss of sound from the bottom of the at least one speaker enclosure. Preferably, the bottom reflecting panel is connected to the rear reflecting panel at 50° to 150°. More preferably, the bottom reflecting panel is substantially horizontal. Preferably, the bottom reflecting panel is substantially horizontal if the at least one speaker enclosure is adapted, in use, to rest on the floor. The bottom reflecting panel may be formed by a floor. Preferably, a substantial portion of the sound generated by the at least one speaker exits the reflective horn from one side of the at least one speaker enclosure.

Preferably, the reflective horn also includes a side reflecting panel. The preferably side reflecting panel, in use, acts to prevent the substantial loss of sound from the other side of the at least one speaker enclosure. The side reflecting panel may be formed by a wall. Alternatively, the speaker enclosure includes two side reflecting panels. In this case, the top reflecting panel is above the top of the enclosure, leaving a space for a substantial portion of sound to exit the reflective horn. Preferably, the speaker faces away from the listening area. Alternatively, the speaker faces the listening area. In this case, the sound is reflected at least twice by the device before entering the listening area.

Preferably, the reflective horn is constructed of timber, plastic or metal or any other suitable reflective material. The panels of the reflective horn may be curved or shaped in various ways for either acoustic or ornamental purposes. The at least one speaker enclosure may be in the form of a floor standing speaker enclosure, a floor standing tower speaker enclosure, a wall mounted speaker enclosure, an inverted ceiling mounted speaker enclosure, a twin speaker enclosure, a stage monitor speaker enclosure, or a spherical speaker enclosure. The speaker system may, for example, comprise two speaker enclosures; a right-channel speaker enclosure and a left-channel speaker enclosure. Preferably, the right and left channel speaker enclosures are separated by a distance of 1 m to 10 m. Preferably, the left and right channel speaker enclosures are arranged, in use, to direct sound through the space between them.

According to a second aspect of the present invention, there is provided a speaker enclosure as defined by the first aspect

Throughout this specification and the claims, the words “comprise”, “comprises,” and “comprising” are used in a non-exclusive sense, except where the context requires otherwise.

### BRIEF DESCRIPTION OF THE DRAWINGS

Preferred embodiments of the invention will now be described, by way of example only, with reference to the accompanying drawings in which:

FIG. 1 is a plan view of a speaker system of the present invention, including two floor standing speaker enclosures;

FIG. 2 is an angled elevated view of one of the floor standing speaker enclosures of FIG. 1;

FIG. 3 is a rear view of the floor standing speaker enclosure of FIG. 1;

FIG. 4 is a front view of the floor standing speaker enclosure of FIG. 1;

FIG. 5 is a side view of the floor standing speaker enclosure of FIG. 1;

FIG. 6 is an underneath view of the floor standing speaker enclosure of FIG. 1;

FIG. 7 is a reverse side view of the floor standing speaker enclosure of FIG. 1;

FIG. 8 is an angled elevated view of an alternative embodiment of the speaker enclosure of FIG. 1, being a floor standing tower speaker enclosure;

FIG. 9 is an angled elevated view of an alternative embodiment of the speaker enclosure of FIG. 1, being a wall mounted speaker enclosure;

FIG. 10 is an angled underneath view of an alternative embodiment of the speaker enclosure of FIG. 1, being an inverted ceiling mounted speaker enclosure;

FIG. 11 is a plan view of an alternative speaker system of the present invention, comprising two floor standing speaker enclosures;

FIG. 12 is an angled elevated view of one of the floor standing speaker enclosures of FIG. 11;

FIG. 13 is a rear view of the floor standing speaker enclosure of FIG. 11;

FIG. 14 is a front view of the floor standing speaker enclosure of FIG. 11;

FIG. 15 is a side view of the floor standing speaker enclosure of FIG. 11;

FIG. 16 is an underneath view of the floor standing speaker enclosure of FIG. 11;

FIG. 17 is a reverse side view of the floor standing speaker enclosure of FIG. 11;

FIG. 18 is an angled elevated view of an alternative embodiment of the speaker enclosure of FIG. 11, being a floor standing tower speaker enclosure;

FIG. 19 is an angled elevated view of an alternative embodiment of the speaker enclosure of FIG. 11, being a wall mounted speaker enclosure;

FIG. 20 is an angled underneath view of an alternative embodiment of the speaker enclosure of FIG. 11, being an inverted ceiling mounted speaker enclosure;

FIG. 21 is an angled elevated view of an alternative speaker system of the present invention, comprising a twin speaker enclosure;

FIG. 22 is a plan of the twin speaker enclosure of FIG. 21;

FIG. 23 is a bottom view of the twin speaker enclosure of FIG. 21;

FIG. 24 is a front view of the twin speaker enclosure of FIG. 21;

FIG. 25 is a rear view of a twin speaker enclosure of FIG. 21;

FIG. 26 is a side view of the twin speaker enclosure of FIG. 21;

FIG. 27 is a reverse side view of the twin speaker enclosure of FIG. 21;

FIG. 28 is an angled elevated view of an alternative speaker system of the present invention, comprising a floor standing speaker enclosure;

FIG. 29 is a plan view of the floor standing speaker enclosure of FIG. 28;

FIG. 30 is a front view of the floor standing speaker enclosure of FIG. 28;

FIG. 31 is a side view of the floor standing speaker enclosure of FIG. 28;

FIG. 32 is a reverse side view of the floor standing speaker enclosure of FIG. 28;

FIG. 33 is a bottom view of the floor standing speaker enclosure of FIG. 28;

FIG. 34 is a rear view of the floor standing speaker enclosure of FIG. 28;

FIG. 35 is a plan view of an alternative embodiment of the speaker enclosure of FIG. 28, being a wall mounted speaker enclosure;

FIG. 36 is a front view of the wall mounted speaker enclosure of FIG. 35;

FIG. 37 is a side view of the wall mounted speaker enclosure of FIG. 35;

FIG. 38 is a reverse side view of the wall mounted speaker enclosure of FIG. 35;

FIG. 39 is a rear view of the wall mounted speaker enclosure of FIG. 35;

FIG. 40 is a bottom view of the wall mounted speaker enclosure of FIG. 35;

FIG. 41 is an angled elevated view of the wall mounted speaker enclosure of FIG. 35;

FIG. 42 is a plan view of an alternative embodiment of the speaker enclosure of FIG. 28, being an inverted ceiling mounted speaker enclosure;

FIG. 43 is a front view of the inverted ceiling mounted speaker enclosure of FIG. 42;

FIG. 44 is a side view of the inverted ceiling mounted speaker enclosure of FIG. 42;

FIG. 45 is a reverse side view of the inverted ceiling mounted speaker enclosure of FIG. 42;

FIG. 46 is a rear view of the inverted ceiling mounted speaker enclosure of FIG. 42;

FIG. 47 is a top view of the inverted ceiling mounted speaker enclosure of FIG. 42;

FIG. 48 is an angled underneath view of the inverted ceiling mounted speaker enclosure of FIG. 42;

FIG. 49 is a plan view of an alternative embodiment of the speaker enclosure of FIG. 28, being a floor standing stage monitor speaker enclosure;

FIG. 50 is a rear view of the stage monitor speaker enclosure of FIG. 49;

FIG. 51 is a side view of the stage monitor speaker enclosure of FIG. 49;

FIG. 52 is a front view of the stage monitor speaker enclosure of FIG. 49;

FIG. 53 is a reverse side view of the stage monitor speaker enclosure of FIG. 49;

FIG. 54 is a bottom view of the stage monitor speaker enclosure of FIG. 49;

FIG. 55 is an angled elevated view of the stage monitor speaker enclosure of FIG. 49;

FIG. 56 is a cut-away side view of a vehicle with the speaker enclosure of FIG. 28 mounted on the rear window shelf;

FIG. 57 is a cut-away side view of a vehicle having the speaker enclosure of FIG. 28 mounted on the rear door or rear panel;

FIG. 58 is an angled elevated view of an alternative speaker system with the present invention, comprising a floor standing spherical speaker enclosure;

FIG. 59 is a side view of the spherical speaker enclosure of FIG. 58;

FIG. 60 is a reverse side view of the spherical speaker enclosure of FIG. 58;

FIG. 61 is a side view of the spherical speaker enclosure of FIG. 58;

FIG. 62 is a front view of the spherical speaker enclosure of FIG. 58;

FIG. 63 is a rear view of the spherical speaker enclosure of FIG. 58;

FIG. 64 is a plan view of the spherical speaker enclosure of FIG. 58; and

FIG. 65 is a bottom view of the spherical speaker enclosure of FIG. 58.

### DETAILED DESCRIPTION OF THE INVENTION

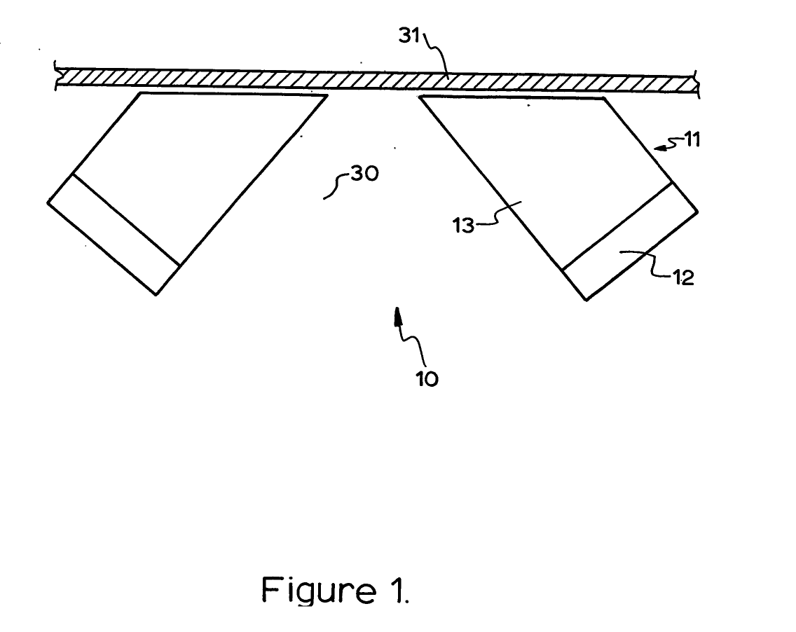

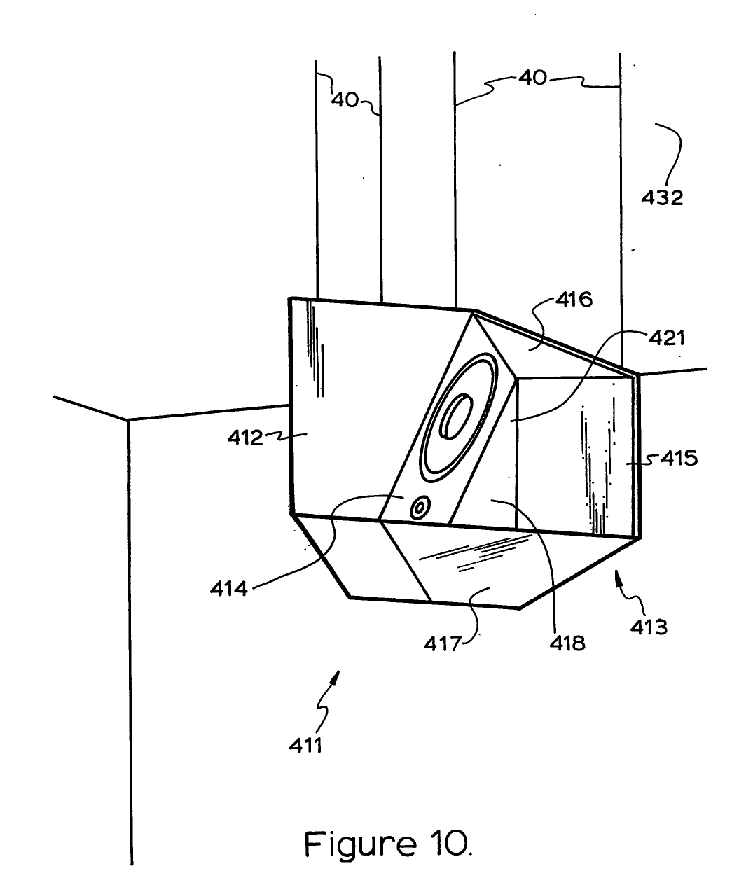

Referring firstly to FIG. 1, a speaker system 10 is shown including two speaker enclosures 11, a right channel speaker enclosure and a left-channel speaker enclosure. The speaker system 1.0 of the present invention is not limited to the number or arrangement of speakers. The speaker enclosures 11 shown in FIG. 10, are floor standing speakers, such that they rest on the floor 30. The speaker enclosures 11 may or may not lie up against a wall 31 as shown. The separation distance between the closest points of the two speaker enclosures 11 is between 1 and 10 metres.

The speaker system 10 is adapted, in use, to provide a listener with sound which is entirely reflected. Without wishing to be bound by theory, the effect of reflecting the sound is that all frequencies are blended to propagate coherent dynamic sound, such that no frequency band overwhelms another.

The Fletcher hertz decibel graph of human hearing responsiveness at low sound pressure levels shows that mid-range frequencies are relatively linear when compared to bass and treble frequencies, which are rolled-off or heard at a lower sound pressure level and thus require boosting to be linear with mid-range sound pressure levels. The speaker system 10 propagates at substantially linear sound pressure levels.

As a result, the listener receives an increased density of sound across a wider central sound stage, at high and low sound pressure levels. Thus, using the speaker system 10 of the present invention, the listener is able to clearly hear dynamic upper bass frequencies as low as 70 to 80 decibels, and at a listening position as close as one metre to the speaker system 10. Furthermore, the quality of sound is improved by dispersing the sound away from the walls, floor and ceiling.

The speaker system 10 can be driven by an analogue or digital format from left and right outputs or by a multi-channel processor output using conventional reproduction equipment for either indoor or outdoor purposes.

The left and right channel speaker enclosures 11 are mirror images of each other, and are adapted, in use, to reflect sound primarily through the space between them. This avoids problems of diffraction, echo and transmission time delay for the sound to reach the listener.

Each speaker enclosure 11 comprises an enclosure 12 and a reflective horn 13. The enclosure 12 houses a speaker or speakers including conventional electronic equipment for producing sound, including at least one transducer for the conversion of electrical energy to acoustic energy. Any conventional transducers can be used, however, a higher quality of sound is produced when an electro dynamic moving coil bass transducer and a compression driver for middle and high frequencies are used. The diameter of the bass driver is approximately 38 cm.

The reflective horn 13 propagates, reflects and transmits the sound from the speaker to the listener. The effect of the reflective horn 13 is to increase the dynamic range and enhance the sound of percussive musical instruments such as a piano, drums, and symbols for stereo and multi-channel transient sound effects.

Within the reflective horn 13, the sound pressure level is higher than the sound pressure level at the exit point for the sound from the horn 13. This higher sound pressure level within the reflective horn 13, generates higher dynamic range and increases bass frequency sound pressure levels in the listening area. Bass frequencies tend to be omnidirectional and the reflective horn 13 concentrates the transmission of bass frequencies with comparatively narrow dispersion and more directly concentrated sound to listeners. The sound is therefore transmitted away from the walls, floor and ceiling and this substantially overcomes the problems of bass standing waves within the listening area. Also, due to the reflection of middle and high frequencies, these frequencies do not overwhelm the bass frequency resolution, and therefore what is heard by the listener is high fidelity resolution of sound which has a sense of natural weight propagated by the deep, dynamic, defined bass.

Each speaker enclosure 11 is arranged, in use, so that the speaker is facing the wall 31 (away from the listening area) and is separated from the wall by the reflective horn 13. The enclosure 12 is attached to the reflective horn 13 and projects away from the wall 31. The reflective horn 13 has an opening to one side which is the exit point for the sound from the reflective horn 13 and allows the sound to be transmitted out to the listener in the listening area.

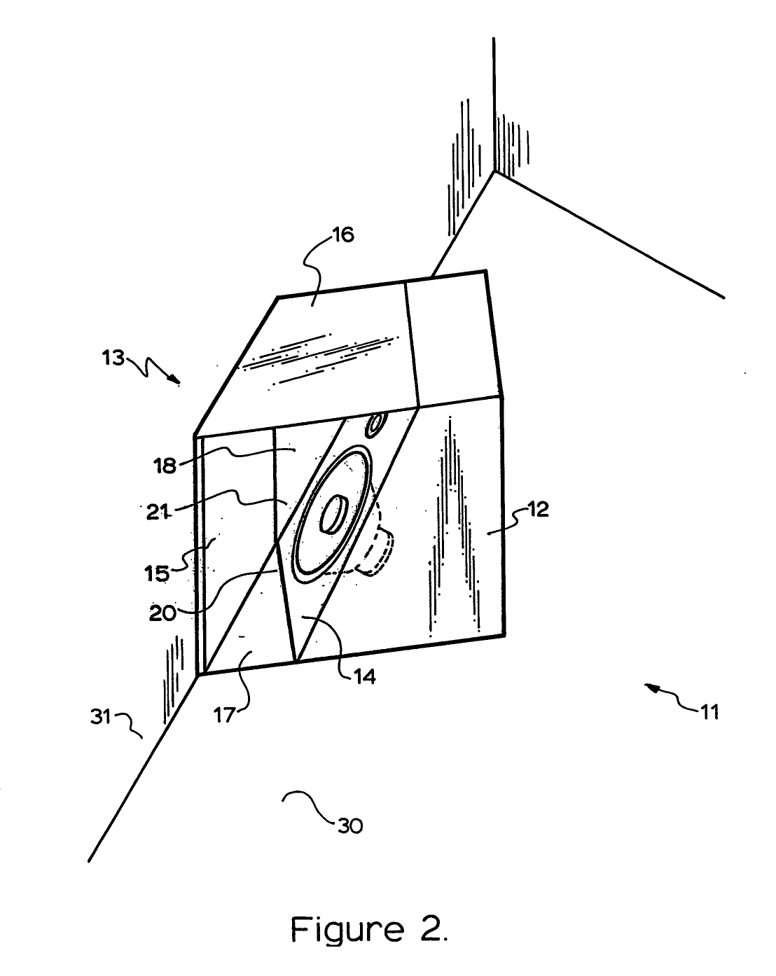

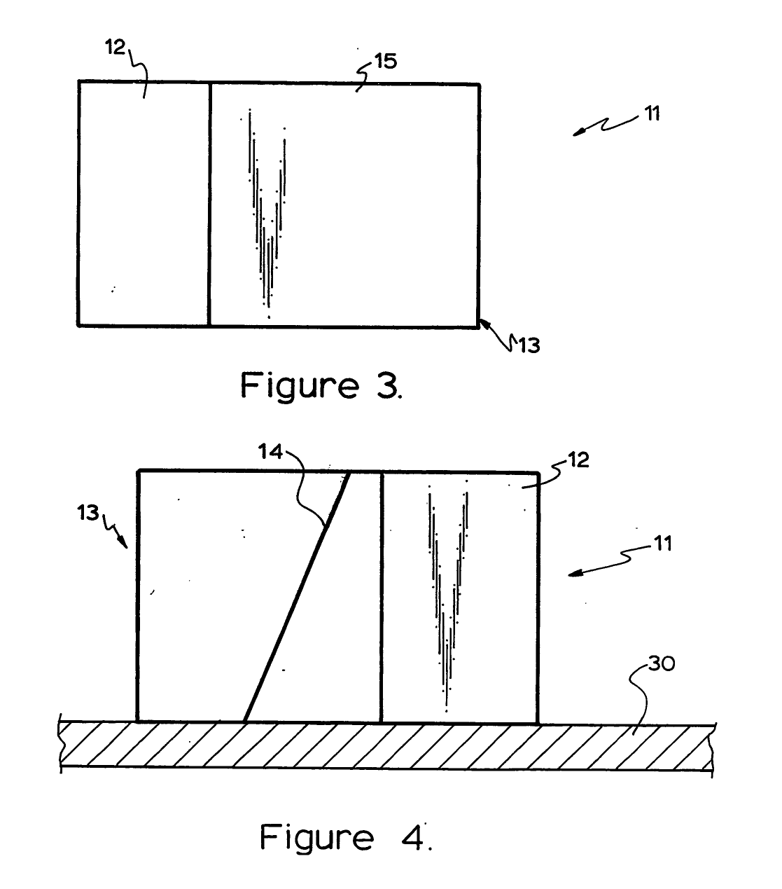

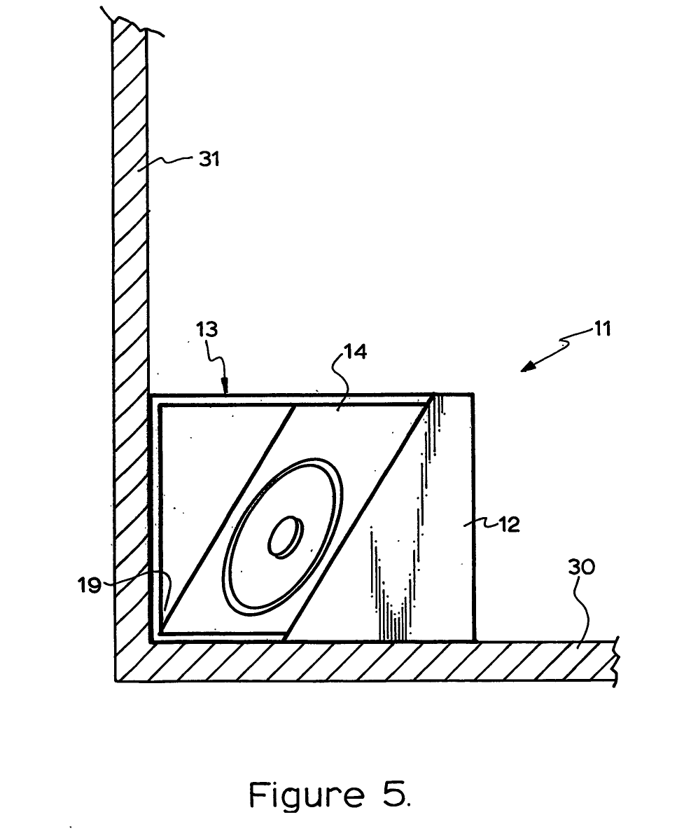

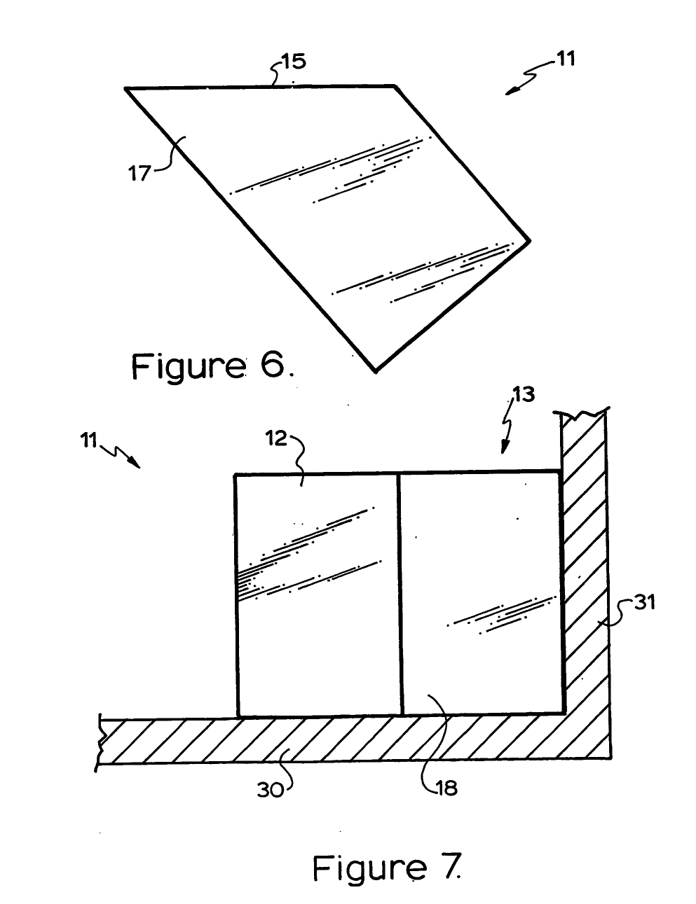

Referring now to FIGS. 2 to 7, the reflective horn 13 of each speaker enclosure 11, comprises a baffle panel 14, a rear reflecting panel 15, a top reflecting panel 16, a bottom reflecting panel 17 and a side reflecting panel 1.8. The baffle panel 14 includes the at least one transducer of the speaker and also forms one wall of the enclosure 12. The baffle panel 14 is facing the rear reflecting panel 15 and is located relative to the rear reflecting panel 15 so that the at least one transducer of the speaker is approximately 10 cm to 30 cm from the rear reflecting panel 15. The baffle panel 14 faces the rear reflecting panel 15 at an angle. The angle between the baffle panel 14 and the rear reflecting panel 15 is referred to as the “toe-in angle,, and is between 20° and 60°. However, the best sound is usually produced when the toe in angle is approximately 40°.

The rear reflecting panel 15 is substantially vertical. The baffle panel 14 is inclined away from the rear reflecting panel 15 at an angle referred to as the “tilt angle” 21. The tilt angle 21 of the baffle panel 14 can be between 0° to 60°. Although the tilt angle 21 can be greater than 60°, the acoustic quality at higher tilt angles 21 is significantly reduced. However, with the speaker 11 located on the floor 30, it is preferable that the tilt angle 21 is 30°. The baffle panel 14 is inclined so that the sound is reflected towards the ears of the listener. Therefore, generally as the position of the speaker above the ground is increased, the tilt angle 21 required reduces, up to a height of 1 m to 1.5 m, where the tilt angle 21 should be 0°. Above 1 m to 1.5 m, the tilt angle 21 required is increased so that the baffle panel 14 is inclined to reflect sound to the listener.

The top reflective panel 16 is connected to the tops of the baffle panel 14 and the rear reflecting panel 15. The angle at which the top reflecting panel 16 is connected to the rear reflecting panel 15 can vary between 50° and 150°. However, it is best if the top reflecting panel 16 is substantially horizontal to avoid loss of sound to the ceiling.

With the speaker 11 resting on the ground, the bottom reflecting panel 17 is substantially horizontal. With the speaker 11 arranged in this way, the floor 30 may act as the bottom reflecting panel 17. Furthermore, if the speaker 11 is up against the wall 31, the wall 31 may act as the rear reflecting panel 15.

Sound leaves the speaker enclosure 11 through the opening in the reflective horn 13 which is to one side of the baffle panel 14. For the right channel speaker enclosure 11 shown in FIGS. 2 to 7, the opening in the reflective horn 13 is on the left-hand side of the baffle panel 14 when facing the wall. For a left channel speaker enclosure 11, the opening would be on the right-hand side. On the other side of the baffle panel 14 to the opening, there is the side reflecting panel 18, which acts to prevent sound escaping from the wrong side of the reflective horn 13.

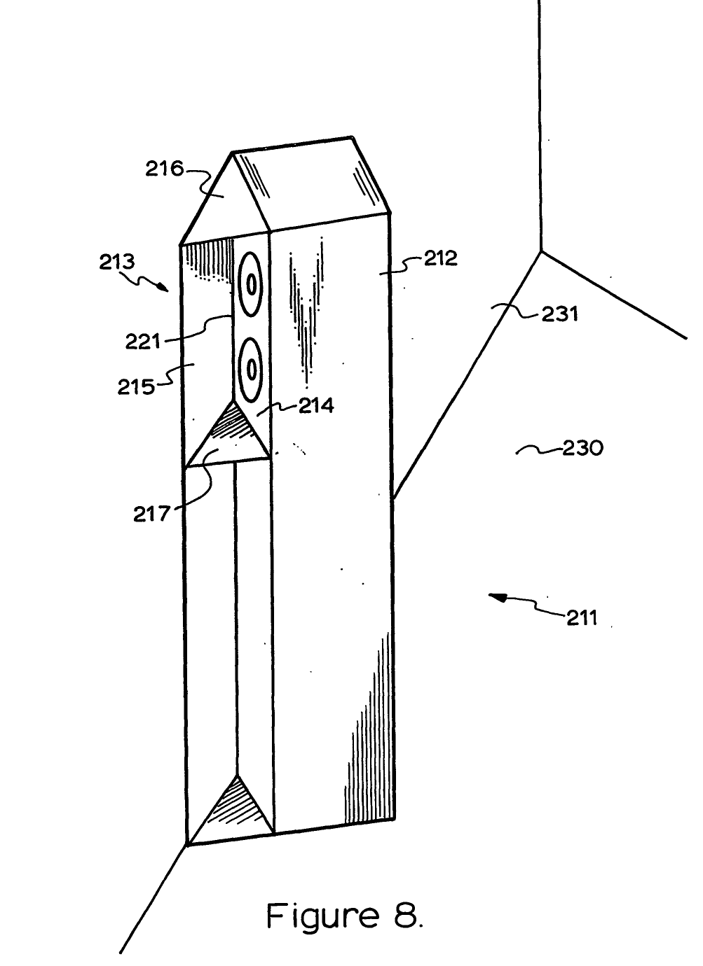

Referring now to FIG. 8, an alternative embodiment of the speaker enclosure of FIG. 1 is shown with the corresponding features being designated with the same numbers but including the prefix numeral 2. The speaker 211 enclosure shown in FIG. 8 is a floor standing tower speaker enclosure, comprising an enclosure 212 and a reflective horn 213. The speaker 211 rests on the floor 230 and is arranged in FIG. 8 up against the wall 231, with the speaker facing the wall 231.

The speaker is located in the upper portion of the speaker enclosure 211, at a height of approximately 1 m to 1.5 m. At this height, the tilt angle is 0° and therefore there is no requirement for a side reflecting panel as part of the reflective horn 213. The reflective horn 213 therefore comprises a baffle panel 214, a rear reflecting panel 215, a top reflecting panel 216 and a bottom reflecting panel 217. The rear reflecting panel 215 and the baffle panel 214 are arranged, in use, substantially vertically. The top reflecting panel 216 and the bottom reflecting panel 217 can be angled to the rear reflecting panel 215 at an angle of between 50° and 150°. However, it is best if the top and bottom reflecting panels 216 and 217 are substantially horizontal to avoid loss of sound to the floor and ceiling. The bottom reflecting panel 217 is located at least 3 cm below the transducer of the floor standing tower speaker 211. The lower portion of the speaker 211 (below the bottom reflecting panel 217), may contain further speakers or alternatively may comprise other features such as a cd rack, shelves or possibly other electronic equipment.

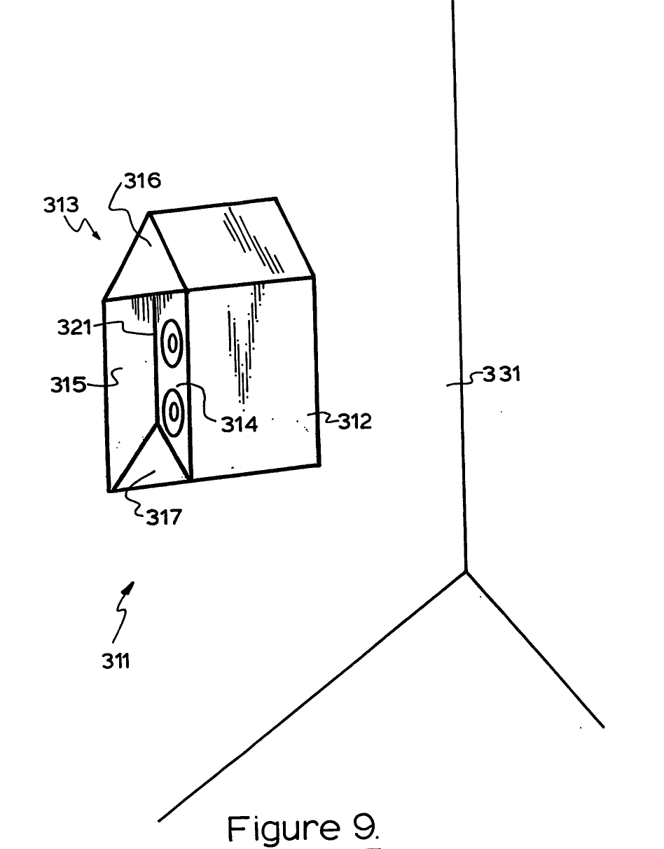

Referring now to FIG. 9, an alternative embodiment of the speaker enclosure of FIG. 1 is shown with the corresponding features being designated with the same numbers but including the prefix numeral 3. The speaker enclosure 311 shown in FIG. 9 is a wall mounted speaker enclosure, comprising an enclosure 312 and a reflective horn 313. The wall mounted speaker enclosure 311 is attached to the wall 331, generally at a height of 1 m to 1.5 m, via bolts, brackets, suitable adhesive pads, rails or other suitable methods for mounting a speaker enclosure on a wall.

With the speaker enclosure 311 mounted at this height, the tilt angle 321 is 0°, so that there is no requirement for the reflective horn 313 to include a side reflecting panel. The reflective horn 313 therefore comprises a baffle panel 314, a rear reflecting panel 315, a top reflecting panel 316 and a bottom reflecting panel 317. The rear reflecting panel 315 and the baffle panel 314 are arranged, in use, substantially vertically. The top reflecting panel 316 and the bottom reflecting panel 317 are angled to the rear reflecting panel 315 at an angle of between 50° and 150° . However, it is best if the top and bottom reflecting panels 316 and 317 are substantially horizontal to avoid loss of sound to the floor and ceiling.

Referring now to FIG. 10, an alternative embodiment of the speaker enclosure of FIG. 1 is shown with the corresponding features being designated with the same numbers but including the prefix numeral 4. The speaker enclosure 411 shown in FIG. 10 is an inverted ceiling mounted speaker enclosure, comprising an enclosure 412 and a reflective horn 413. The speaker enclosure 411 is mounted to the ceiling 432 via bolts, brackets, suitable adhesive pads, rails or other suitable methods for mounting a speaker enclosure to a ceiling. Alternatively, the speaker enclosure 411 is hung from the ceiling 432 by suspension wires 40 as shown in FIG. 10.

The reflective horn 413, comprises a baffle panel 414, a rear reflecting panel 415, a top reflecting panel 416, a bottom reflecting panel 417 and a side reflecting panel 418. The tilt angle 421 can be up to 60°, however, it is preferably 30°. The rear reflecting panel 415 is substantially vertical. The top and bottom reflecting panels 416 and 417 are connected to the rear reflecting panel 415 at an angle of between 50° and 150°.

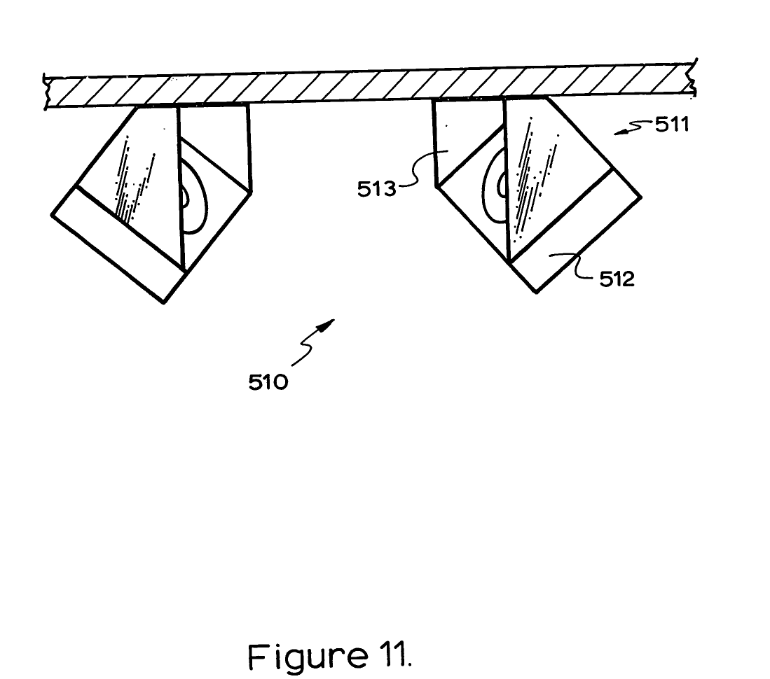

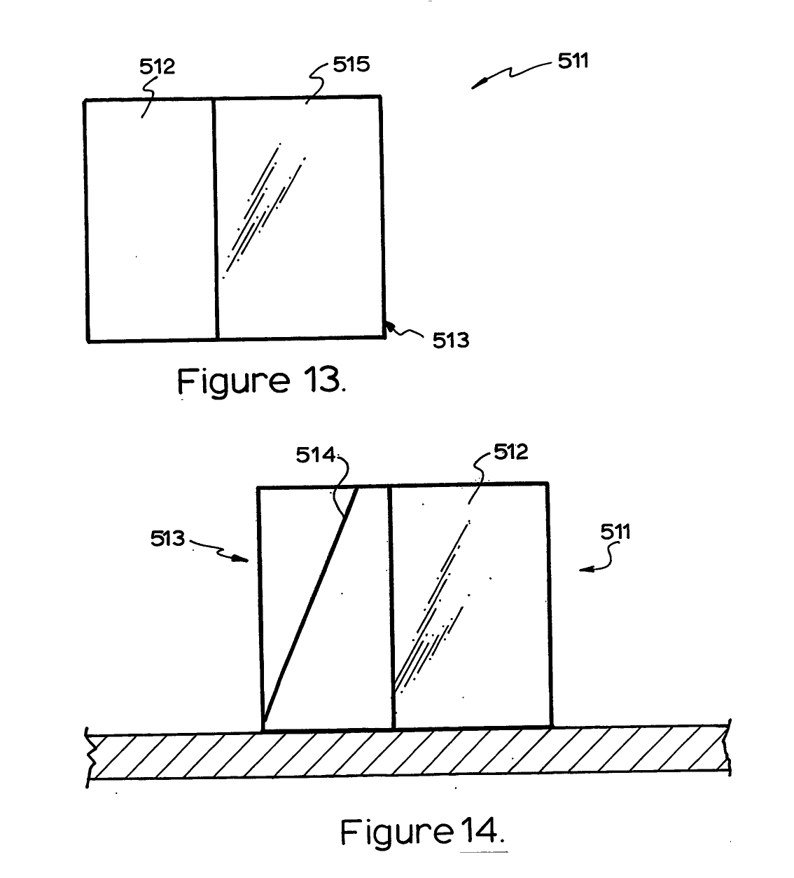

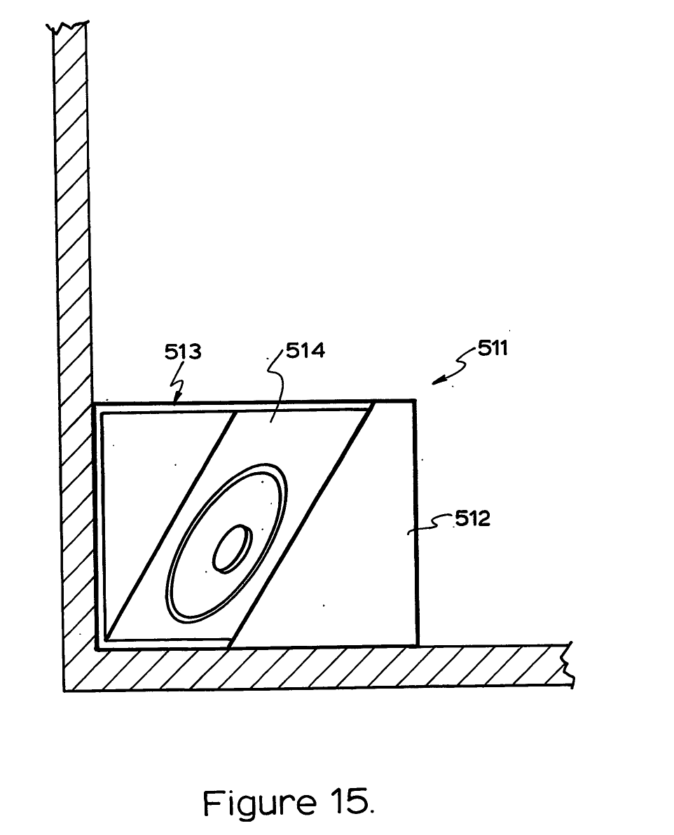

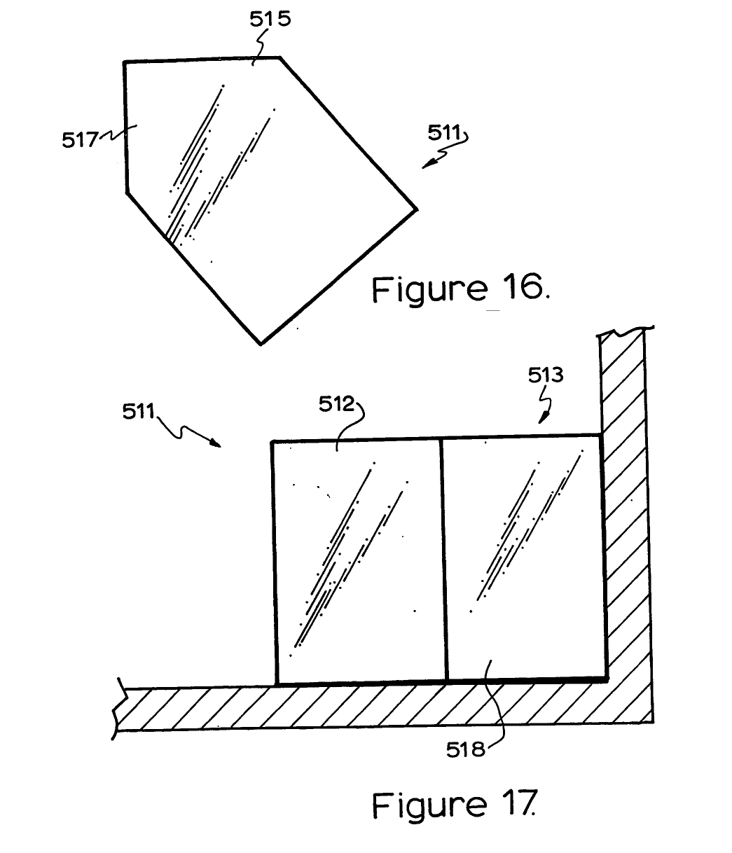

Referring now to FIGS. 11 to 17, an alternative embodiment of the speaker system of FIG. 1 is shown with the corresponding features being designated with the same numbers but including the prefix numeral 5. The speaker system 510 shown in FIG. 11 includes two speaker enclosures 511, a right-channel speaker enclosure and a left-channel speaker enclosure. Each speaker enclosure 511 is a floor standing speaker enclosure, and comprises an enclosure 512 and a reflective horn 513.

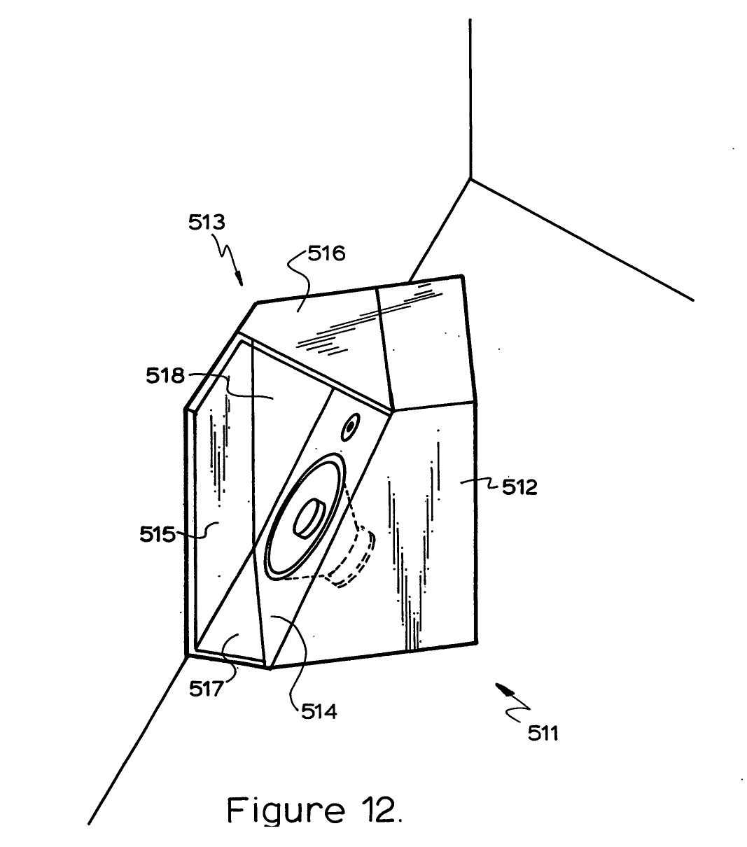

Referring in particular to FIG. 12, the reflective horn 513, includes a baffle panel 514, a rear reflective panel 515, a top reflecting panel 516, a bottom reflecting panel 517 and side reflecting panel 518. The side of the top reflecting panel 516 which is connected to the top edge of the rear reflecting panel 515, is substantially shorter than the length of the top edge. Thus, the reflecting horn 513 has an opening at the top as well as on one side, thus allowing sound to escape from the reflective horn 513 through the top and the side.

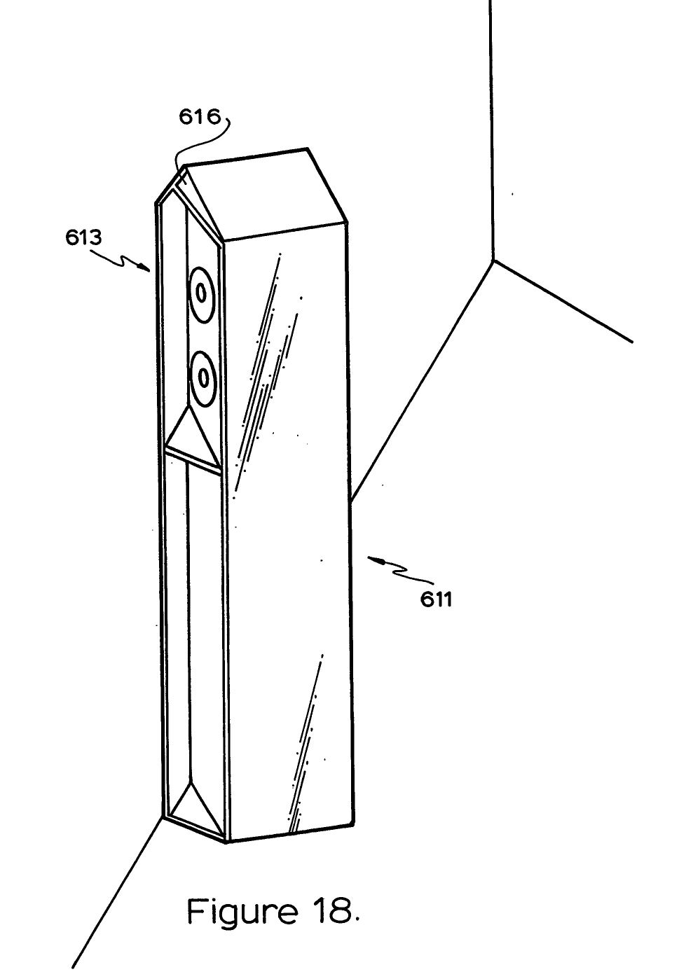

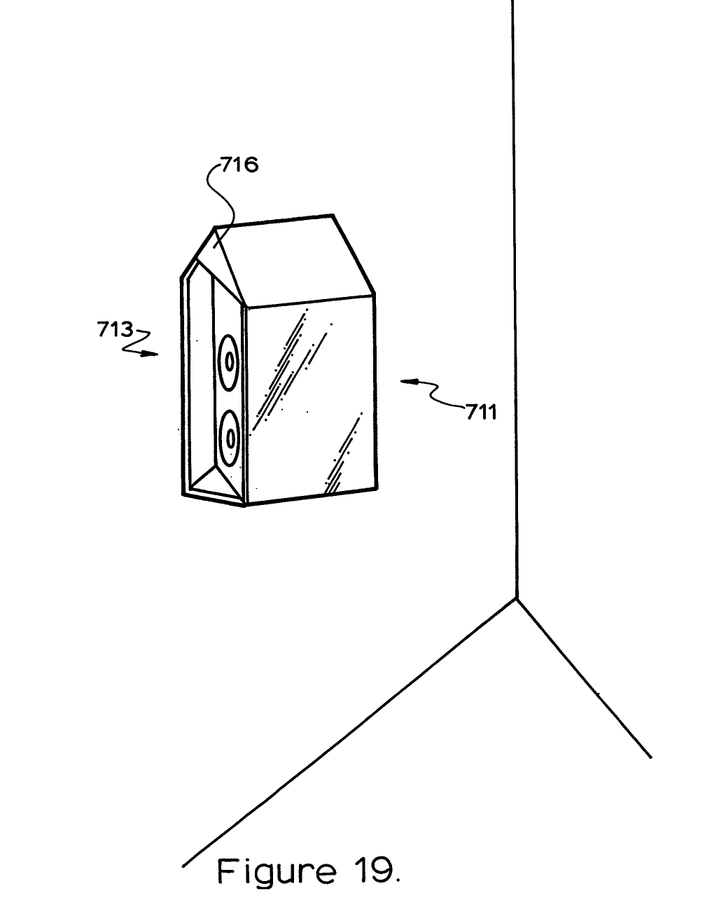

Referring now to FIGS. 18 to 20, alternative embodiments of the speaker enclosure of FIG. 11 are shown in the form of a floor standing tower speaker enclosure 611, a wall mounted speaker enclosure 711 and an inverted ceiling mounted speaker enclosure 811. The speaker enclosures 611, 711 and 811, all have the alternative feature of a top reflecting panel 616, 716 (or bottom reflecting panel 817 in the case of the inverted ceiling mounted speaker enclosure 811) which allows sound to be transmitted from the top (or bottom) as well as the side of a reflective horn 613, 713 and 813.

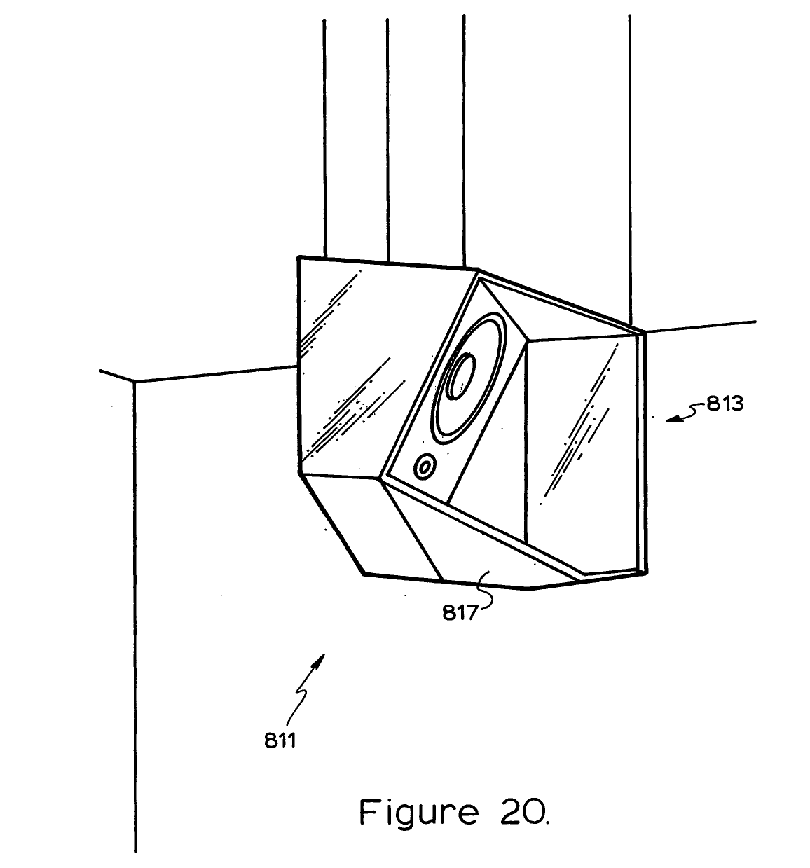

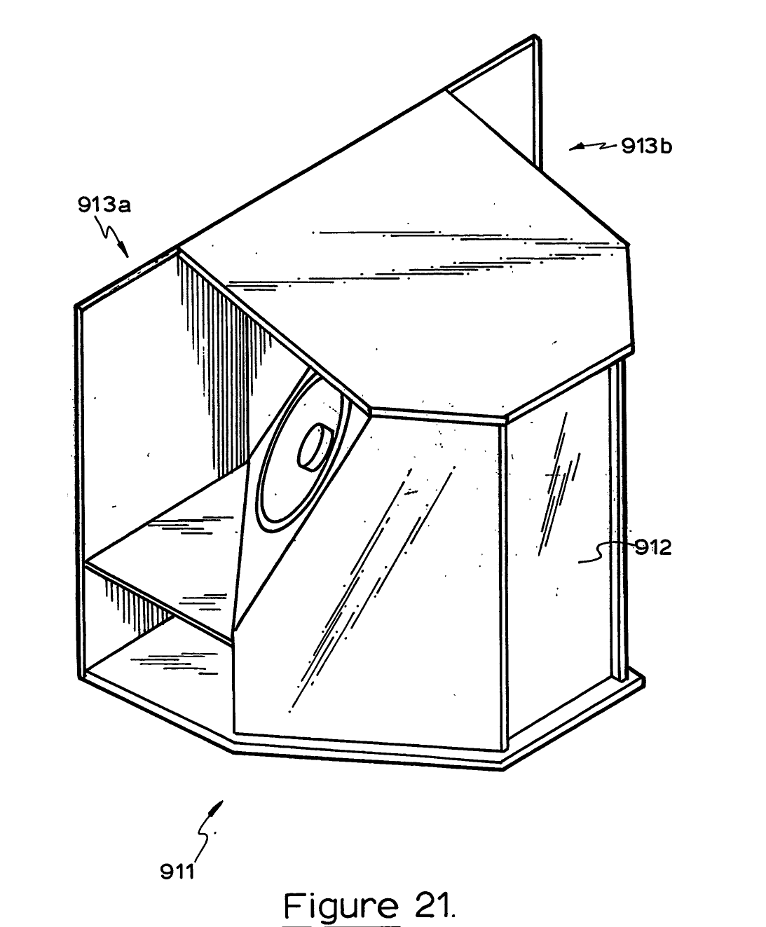

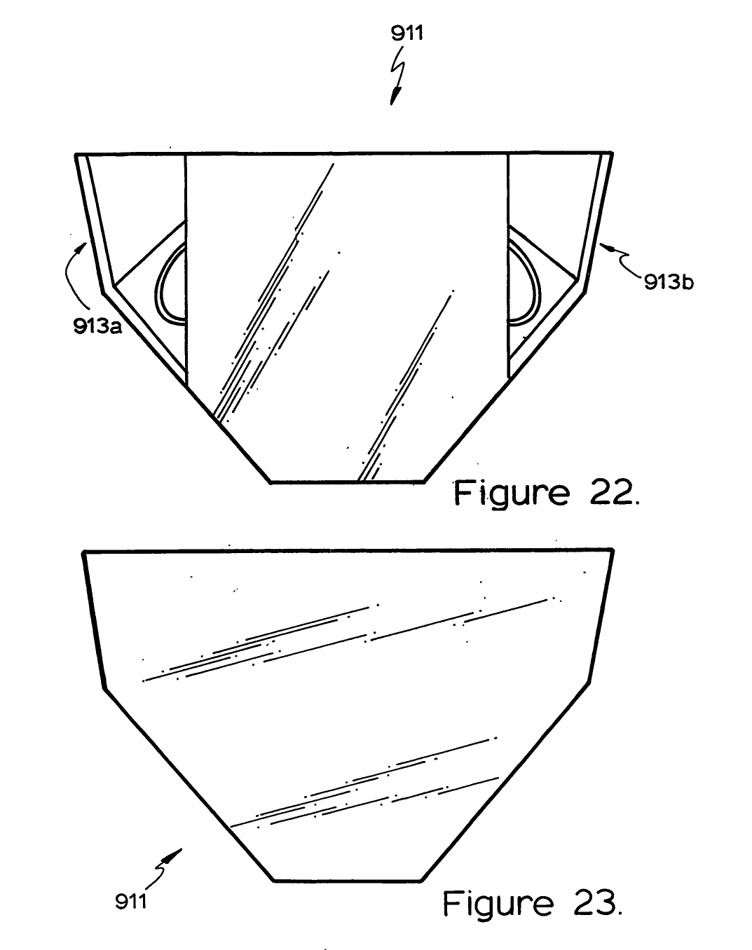

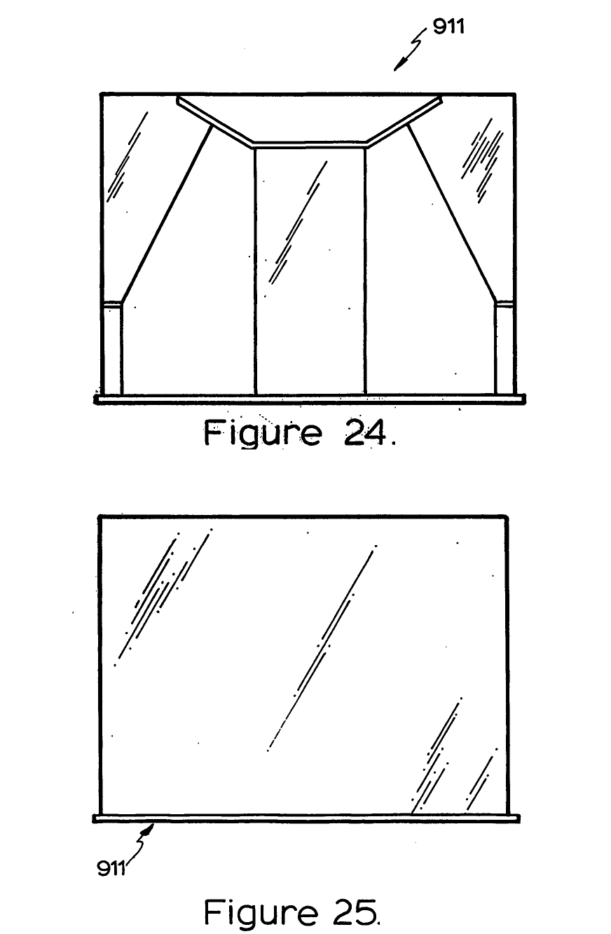

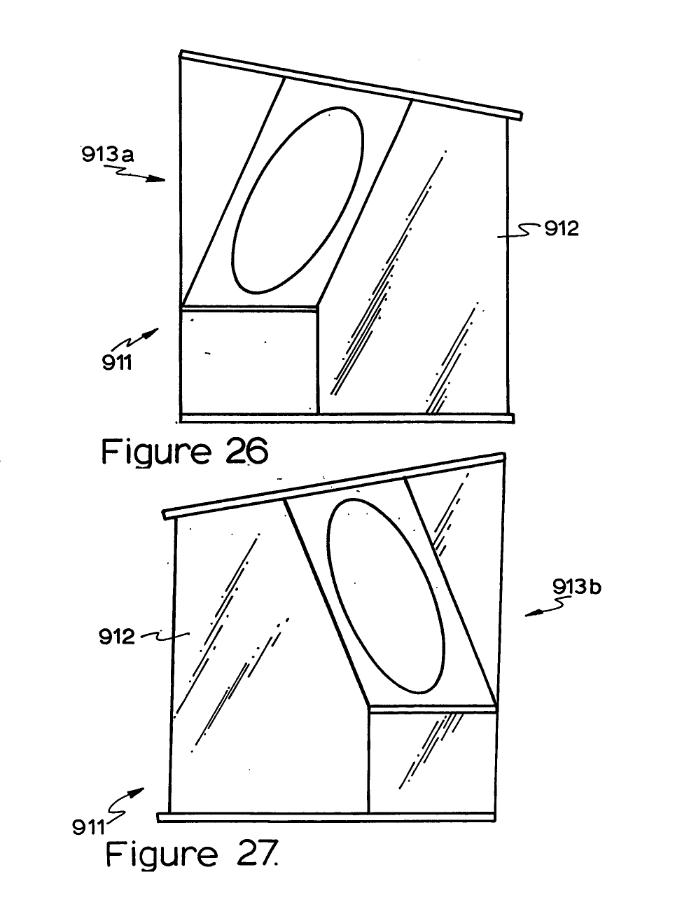

Referring now to FIGS. 21 to 27, an alternative embodiment of the speaker system of FIG. 1 is shown with the corresponding features being designated with the same numbers but including the prefix numeral 9. The speaker system shown in FIGS. 21 to 27 is a twin speaker enclosure 911, comprising a single enclosure 912 and two reflective horns 913a and 913b. The two reflective horns 913a and 913b are located side by side and are adapted in use to direct sound away from each other. Thus, the twin speaker enclosure of FIGS. 21 to 28 is suitable for use in home theatre surround sound systems and vehicle rear window shelf.

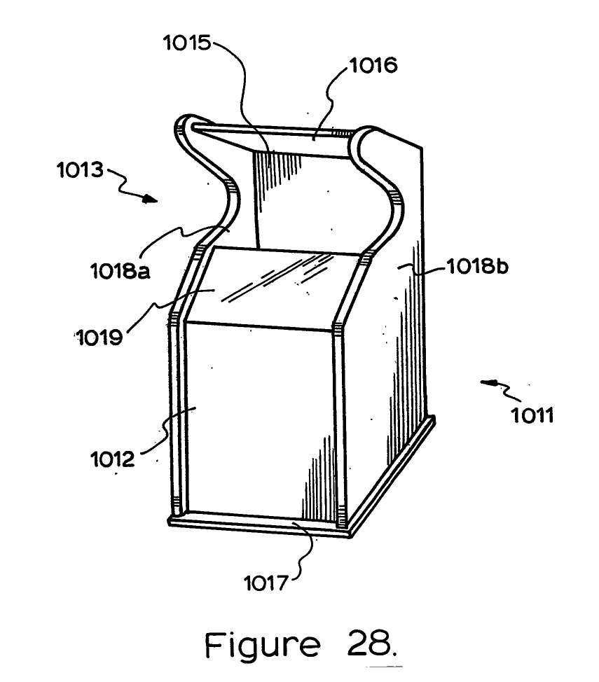

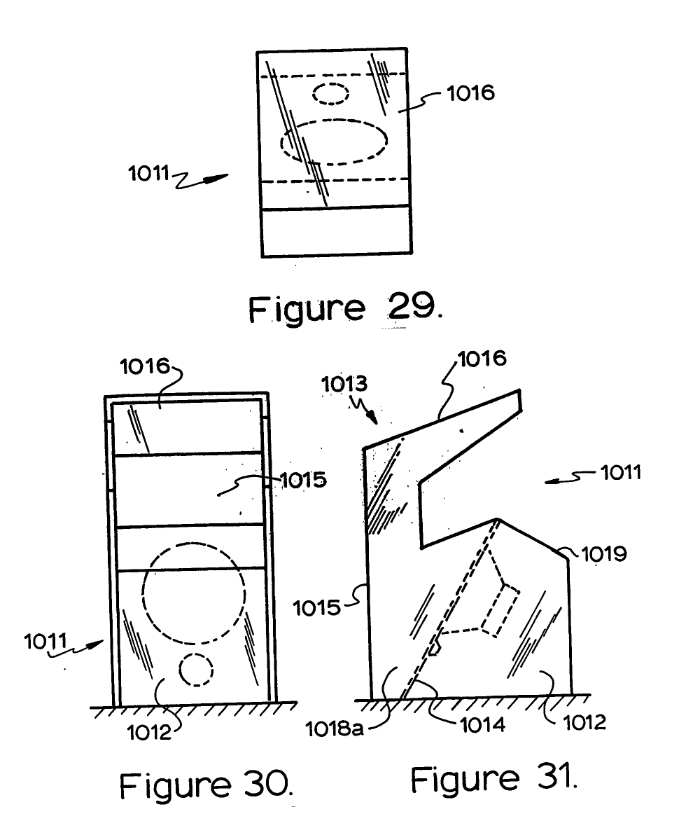

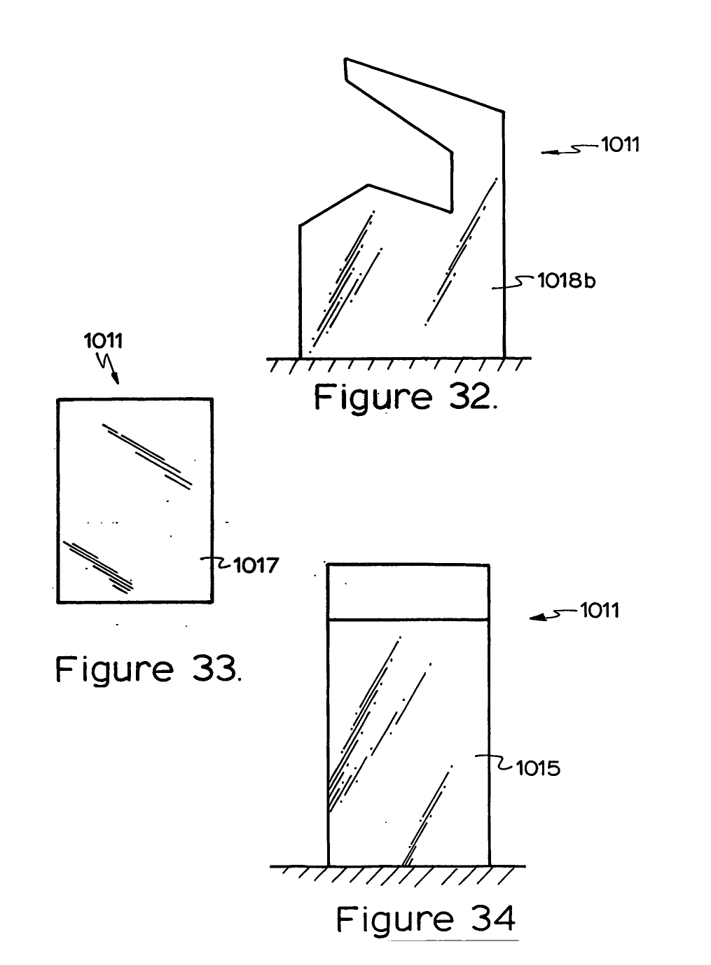

Referring now to FIGS. 28 to 34, an alternative embodiment of the speaker system of FIG. 1 is shown with the corresponding features being designated with the same numbers but including the prefix numeral 10. The speaker system shown in FIGS. 28 to 34 includes a floor standing speaker enclosure 1011 comprising an enclosure 1012 and a reflective horn 1013. The reflective horn 1013 of the speaker enclosure 1011, includes a baffle panel 1014, a rear reflective panel 1015, a top reflecting panel 1016, a bottom reflecting panel 1017 and two side reflecting panels 1018a and 1018b. The top reflecting panel 1016 is located above a top plate 1019 of the enclosure 1012. Thus, sound exits the reflective horn 1013 from the front of the speaker enclosure 1011 through the space between the top reflecting panel 1016 and the plate 1019. The top reflecting panel 1016 is connected to the rear reflecting panel 1015 at an angle of 80°-150°, but preferably approximately 110°. The rear reflecting panel 1015 is substantially vertical in FIGS. 28 to 34. However, the rear reflecting panel 1016 can be angled from the vertical to an extent dependent upon the height of the speaker enclosure 1011 relative to the listening area, so that sound can be directed towards the listening area. The side panels 1018a and 1018b are substantially vertical and act in use to prevent sound leaking from the sides of the speaker enclosure 1011. The baffle panel 1014 is angled relative to the rear reflecting panel 1015 by the tilt angle. The baffle panel 1014 is facing the rear reflecting panel 1015 and is located relative to the rear reflecting panel 1015 so that the at least one transducer of the speaker is approximately 10 cm to 30 cm from the rear reflecting panel 1015.

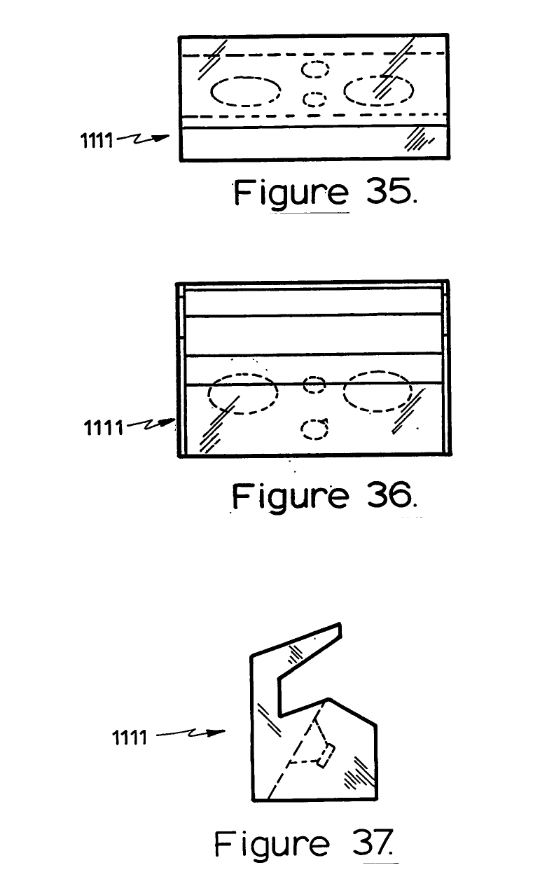

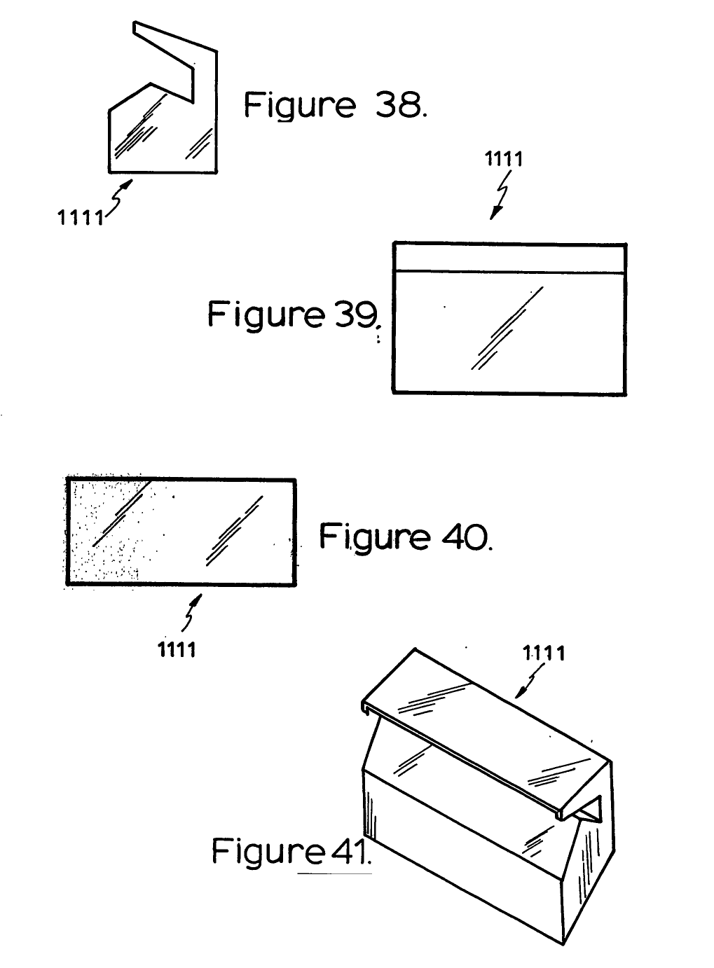

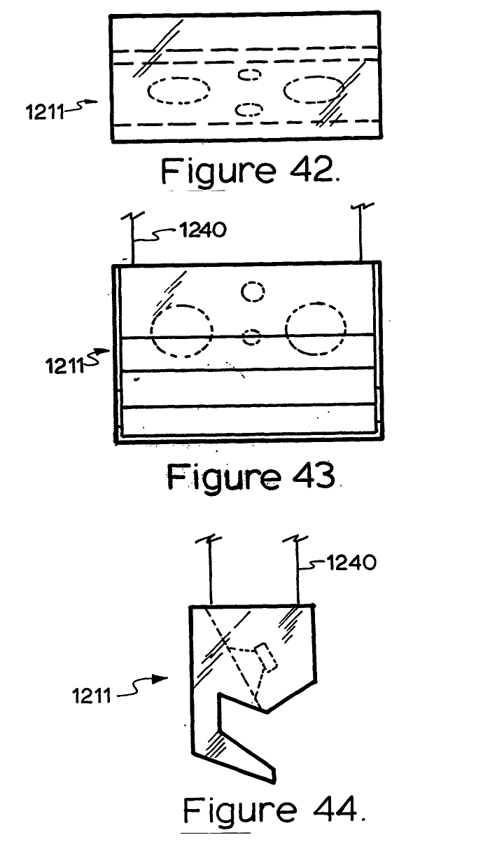

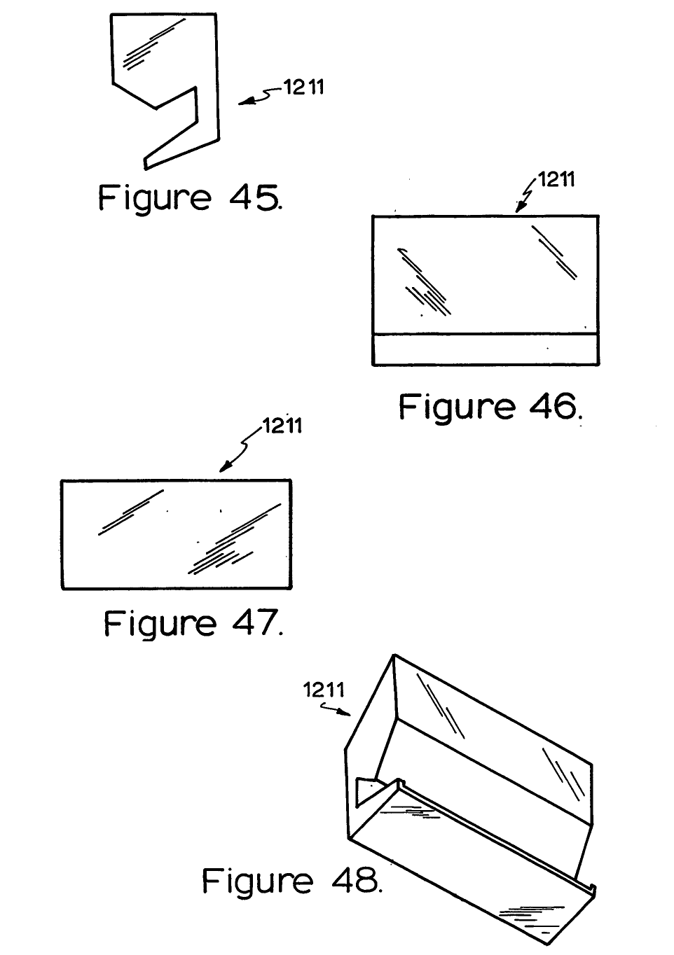

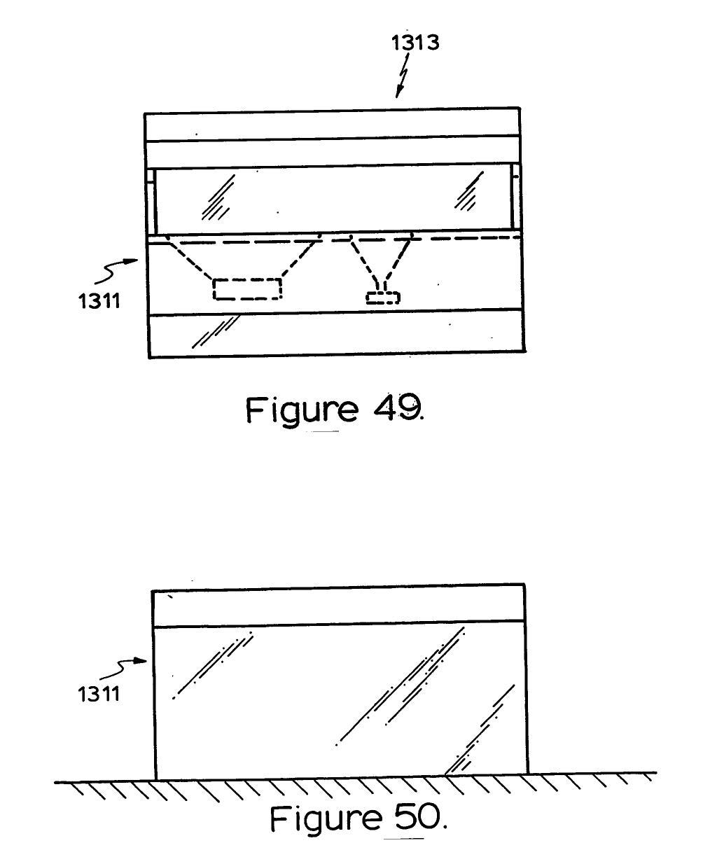

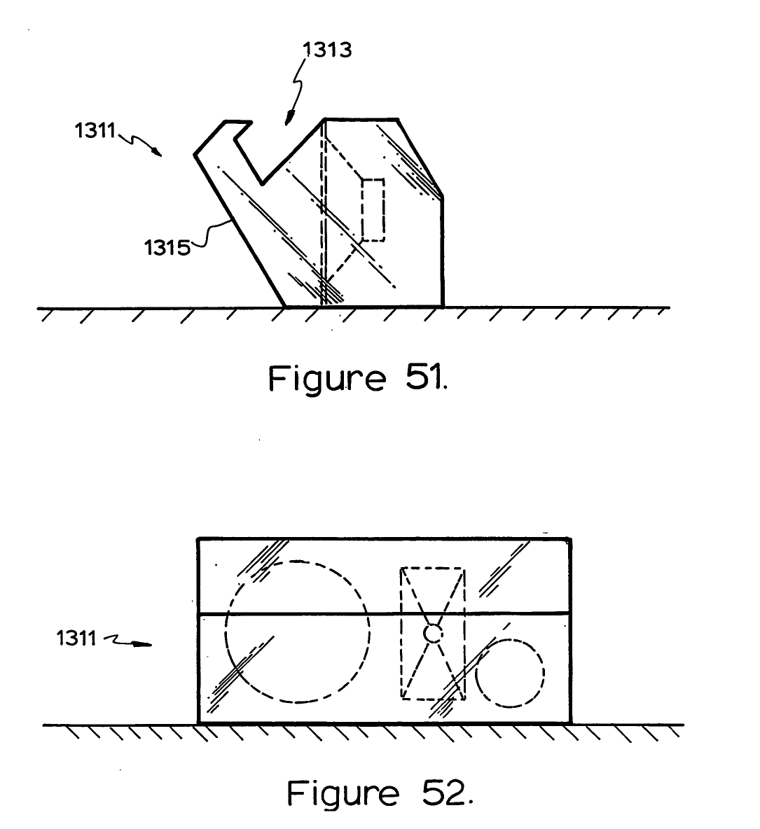

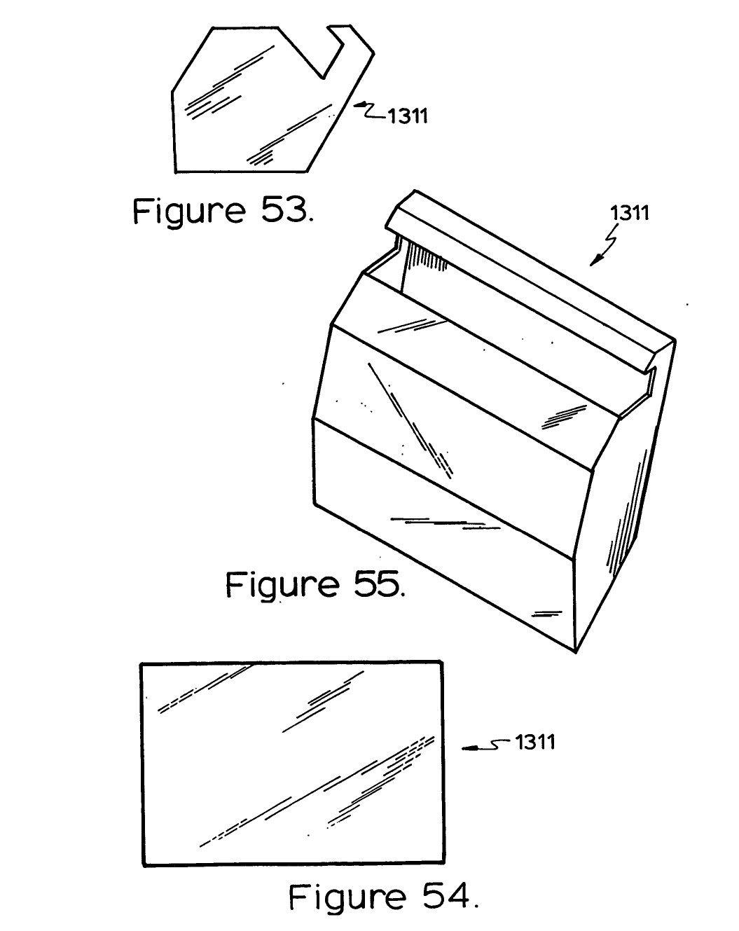

Referring now to FIGS. 35 to 55, alternative embodiments of the speaker enclosure of FIG. 28 are shown in the form of a wall mounted speaker enclosure 1111, an inverted ceiling mounted speaker enclosure 1211 and a stage monitor speaker enclosure 1311. The inverted ceiling mounted speaker enclosure 1211 is shown mounted to the ceiling via suspension wires 1240. However, the speaker enclosure 1211, can be mounted to a ceiling via bolts, brackets, suitable adhesive pads, rails or other suitable methods for mounting a speaker enclosure to a ceiling. The stage monitor speaker enclosure 1311 includes a reflective horn 1313 having a rear reflecting panel 1315 which is angled relative to the floor. The rear reflecting panel 1315 is at an angle of 60 to 80° to the floor so that the sound is directed upwards towards the listening area.

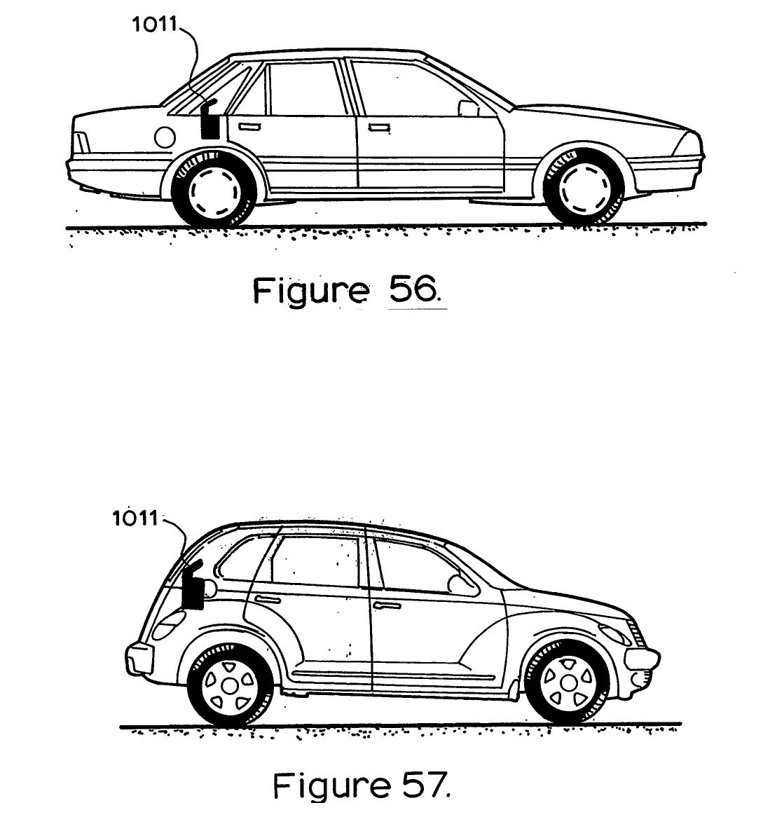

Referring now to FIGS. 56 and 57, the loud speaker enclosure 1011 of FIG. 28 is shown adapted for use 3 in a car. The speaker enclosure 1013. can be mounted either on the rear window shelf of the car as shown in FIG. 56 or on the rear door or rear panel of the vehicle as shown in FIG. 57. In both cases, the speaker enclosure 1011 is adapted, in use to direct sound forward into the interior of the car.

It is understood that the reflective horn 13 is not restricted to having planar panels. Any one or all of the baffle panel, the rear reflective panel, the top reflecting panel, the bottom reflecting panel or the side reflecting panel can be curved or shaped in various ways for either acoustic or ornamental purposes.

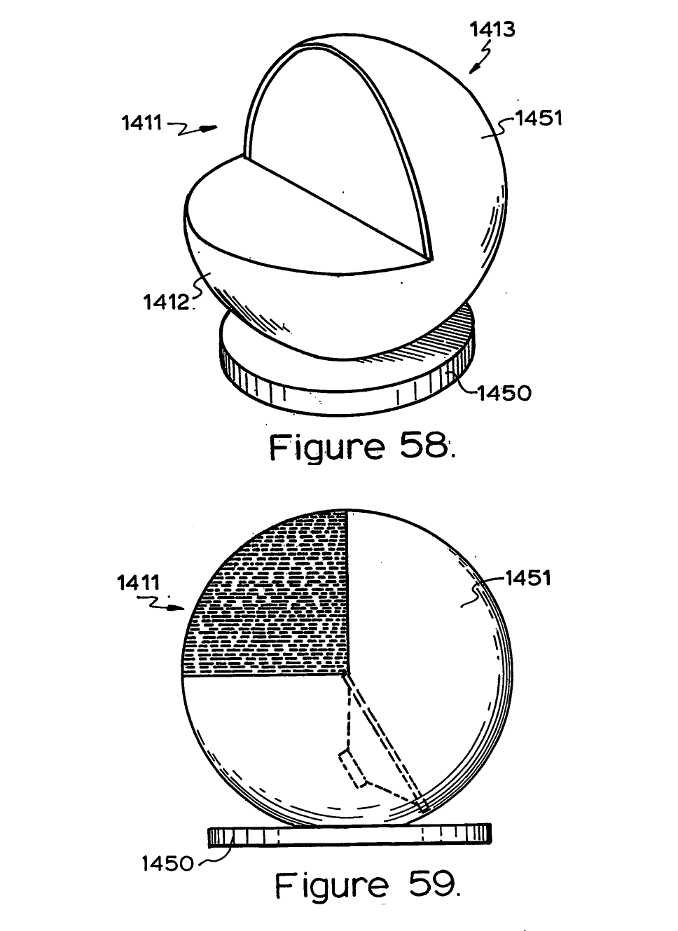

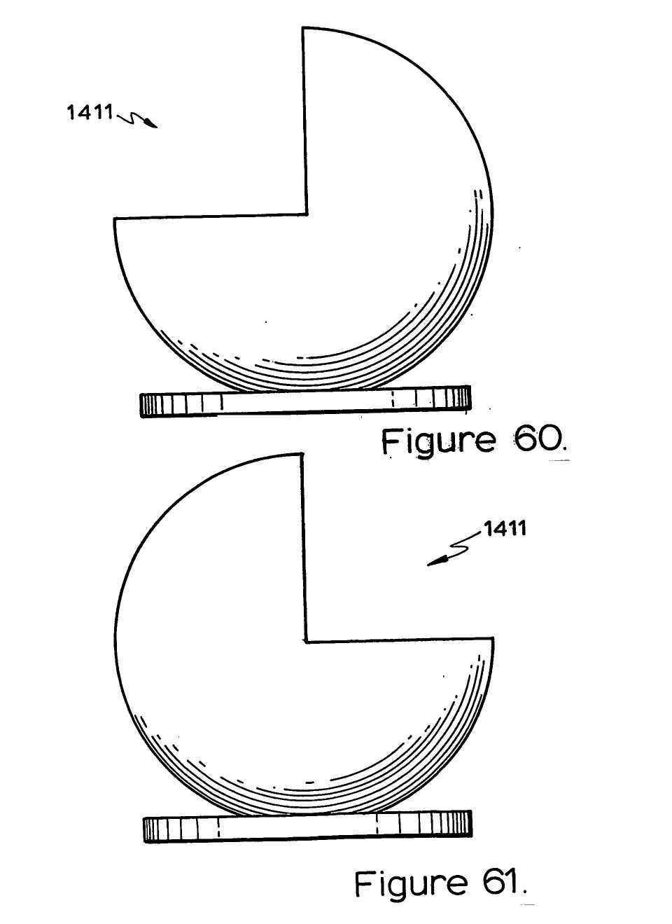

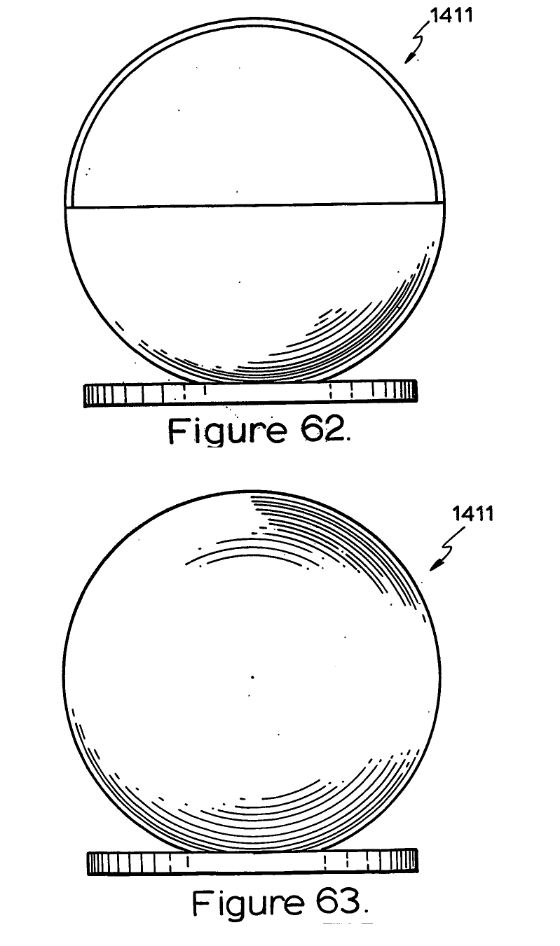

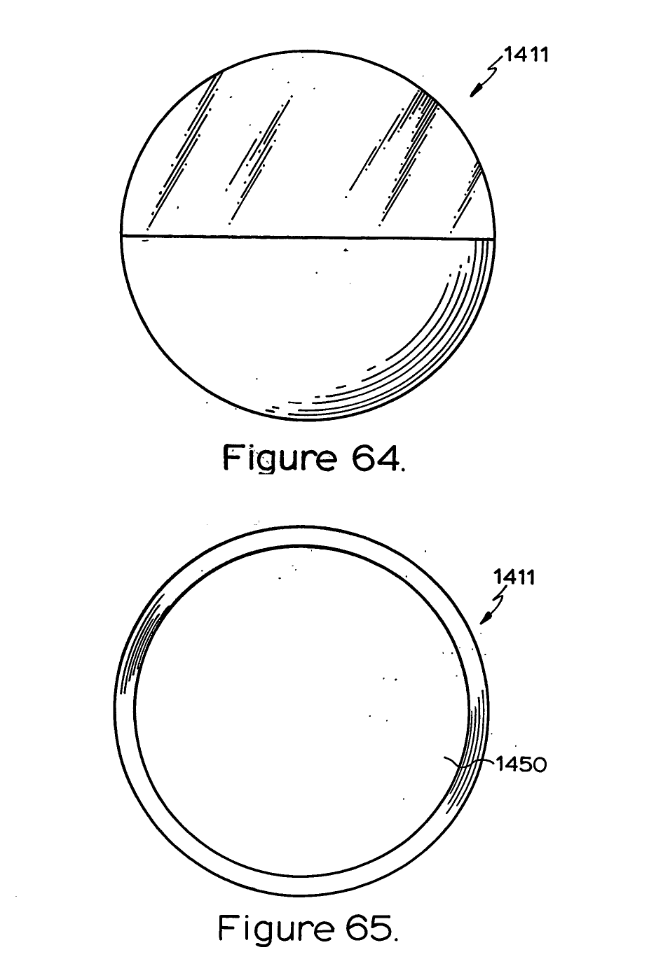

For example, FIGS. 58 to 65 show an alternative embodiment of the speaker system of FIG. 1 with the corresponding features being designated with the same numbers but including the prefix numerate 14. The speaker system shown in FIGS. 58 to 65 is a spherical speaker enclosure 1411, comprising an enclosure 1412 and a reflective horn 1413. The reflective horn 1413, is substantially spherical and instead of a number of panels, comprises a single spherical shell 1451. The spherical shell 1451 is connected to a base plate 1450 so that it can rest easily on the ground. Alternatively the spherical shell 1451 could have a flattened bottom portion.

The speaker enclosure 11, and in particular the reflective horn 13, can be constructed of timber, plastic materials, metal or any other suitable material for acoustic reflection.

1-28. (canceled)

29. A speaker system which transmits sound to a listening area by reflection, the speaker system including:
at least one speaker enclosure comprising an enclosure housing;
at least one electro-acoustic transducer supported on said housing; and
a reflective horn for reflecting sound from said transducer into the listening area, said at least one transducer facing in use away from said listening area, said reflective horn having:
a rear reflecting panel opposite said transducer,
an opening through which sound reflected from said transducer. exits said reflective horn, and
a top reflecting panel defining a boundary of said opening, said top reflecting panel extending at 50° to 150° from said rear reflecting panel.

30. A speaker system as claimed in claim 29, wherein said rear reflecting panel is angled at 20° to 60° to the at least one transducer.

31. A speaker system as claimed in claim 29 wherein the at least one transducer is tilted relative to the rear reflecting panel at an angle of 0° to 60°.

32. A speaker system as claimed in claim 31, wherein when the at least one transducer is at a height of up to 1 m above a floor, the transducer is tilted upwardly, at a zero tilt when between 1 and 1.5 m above a floor, and tilted downwardly when over 1.5 m above a floor.

33. A speaker system as claimed in claim 29 wherein the reflective horn includes a bottom reflecting panel connected to the rear reflecting panel and extending at 50° to 150° to the rear reflecting panel.

34. A speaker system as claimed in claim 29 wherein the reflective horn includes at least one side reflecting panel, said side reflecting panel defining a side boundary of said opening.

35. A speaker system as claimed in claim 34 wherein the reflective horn includes a pair of side reflecting panels, said side reflecting panels defining opposite boundaries of said opening.

36. A speaker system as claimed in claim 35 wherein said opening of said reflective horn is located above said enclosure.

37. A speaker system which transmits sound to a listening area by reflection, the speaker system including:
at least one speaker enclosure comprising an enclosure housing having a baffle panel;
at least one electro-acoustic transducer supported on said baffle panel; and
a reflective horn for reflecting and directing sound from said transducer into the listening area, said baffle panel facing in use in a rearward direction relative to said listening area such that said at least one transducer is directed away from said listening area, said reflective horn having:
a planar or concave reflecting surface opposite said baffle panel, and
an opening through which sound from said transducer reflected from said reflecting surface exits said reflective horn in use towards said listening area.

38. A speaker system as claimed in claim 37 wherein said reflecting surface comprises a planar reflecting surface defined by a planar rear reflecting panel opposite said baffle panel, said baffle panel being tilted away from said rear reflecting panel.

39. A speaker system as claimed in claim 38 wherein said reflective horn includes a further reflecting panel extending from said rear reflecting panel and defining X a boundary of said opening.

40. A speaker system as claimed in claim 39 wherein said reflective horn includes opposite side panels defining opposite boundaries of said opening.

41. A speaker system as claimed in claim 37 wherein said speaker enclosure includes a pair of opposite side panels, said side panels defining sides of said housing and said reflective horn and side boundaries of said opening.

42. A speaker system as claimed in claim 37 wherein said speaker enclosure includes a top reflecting panel defining a top reflecting panel of said reflective horn, said top reflecting panel extending from said rear reflecting panel and defining an upper boundary of said opening, said top reflecting panel extending at 50° to 150° from said rear reflecting panel.

43. A speaker system as claimed in claim 39 wherein said speaker enclosure includes a front panel defining the front of said housing and a top panel extending from said front panel, said top panel defining a lower boundary of said opening, said baffle panel extending from said top panel.

44. A speaker system as claimed in claim 37 wherein said reflective surface comprises a concave reflecting surface defined by a concave panel.

45. A speaker system as claimed in claim 44 wherein said concave panel is defined by the wall of a part spherical shell, said part spherical shell further defining said enclosure housing.

46. A speaker system as claimed in claim 45 wherein said enclosure housing is further defined between a baffle panel extending radially of said shell and a top enclosure housing panel extending radially of said shell.

47. A speaker system as claimed in claim 46 wherein said opening is defined between the shell wall and the top panel.

48. A speaker system as claimed in claim 37, wherein the speaker system comprises two speaker enclosures comprising a right-channel speaker enclosure and a left-channel speaker enclosure, each said enclosure having an associated reflective horn and wherein said openings of the respective horns are opposite each other.
